(19) United States
(12) Patent Application Publication
(10) Pub. No.: US 2006/0194398 A1
(43) Pub. Date: Aug. 31, 2006

(54) Semiconductor device and its manufacturing method

(75) Inventors: Amane Oishi, Kamakura-shi (JP); Taiki Komoda, Yokohama-shi (JP)

Correspondence Address: FOLEY AND LARDNER LLP;SUITE 500, 3000 K STREET NW, WASHINGTON, DC, 20007, US

(73) Assignee: KABUSHIKI KAISHA TOSHIBA

(21) Appl. No.: 11/264,377

(22) Filed: Nov. 2, 2005

(30) Foreign Application Priority Data
Feb. 28, 2005 (JP) 2005-052747

(51) Int. Cl. H01L 21/336; H01L 21/8234

(52) U.S. Cl. 438/305; 438/306; 438/307; 438/303; 438/197

(57) ABSTRACT

A semiconductor device which has a source/drain extension structure suitable for miniaturization, is provided a semiconductor device comprising a gate electrode formed on a semiconductor substrate of a first conductivity type via a gate insulator, a semiconductor region of a second conductivity type comprising first and second semiconductor areas, wherein the first semiconductor area is formed in the semiconductor substrate outside the gate electrode and whose junction depth becomes deeper as apart from the gate electrode, and wherein the second semiconductor area is disposed outside the first semiconductor area and whose junction depth is substantially constant, and an insulator formed to cover a part of the first semiconductor area and in contact with a side face of the gate electrode.

### CROSS-REFERENCE TO RELATED APPLICATIONS

This application is based upon and claims the benefit of priority from prior Japanese Patent Application No. 2005-052747, filed Feb. 28, 2005, the entire contents of which are incorporated herein by reference.

### BACKGROUND OF THE INVENTION

1. Field of the Invention

The present invention relates to a semiconductor device and its manufacturing method, and more particularly to a semiconductor device which has a source/drain extension structure suitable for miniaturization, and its manufacturing method.

2. Description of the Related Art

As a progress of miniaturization of a metal oxide semiconductor filed effect transistor (MOSFET), a source/drain extension (SDE) structure, or lightly doped drain (LDD) structure, has been employed to suppress short channel effects, such as punching-through or the like. SDE includes an extended source/drain with a shallower junction depth and relaxes an electric field at an edge of the source/drain near a gate electrode. For the electric field relaxation, SDE should preferably be formed to be longer in a channel length direction. However, the longer SDE causes a problem of an increase in parasitic resistance.

To suppress the increase in the parasitic resistance of SDE, it is effective to form a SDE in a multiple-step structure in which the junction depth gradually changes. FIG. 1 shows on a relation between the number of SDE steps and a sheet resistance of SDE obtained by calculation. It can be understood from the figure that the sheet resistance of SDE can be reduced more as the number of SDE steps increases. In other words, ideally, forming a SDE comprising an obliquely inclined junction depth whose depth gradually increases as it is apart from the gate electrode is effective for suppressing an increase in the parasitic resistance of SDE.

A technology for forming SDE with multiple steps in which a junction depth changes to suppress an increase in parasitic resistance of SDE is disclosed in Jpn. Pat. Appln. KOKAI Publication No. 8-255903. According to the technology, sidewall insulators of a gate electrode are formed by a plurality of times to be gradually made thicker. After each sidewall insulator is formed, ion implantation is carried out with different conditions each other to form a junction depth of each part of SDE being shallower and a dopant concentration thereof being lower closer to the gate electrode. This method has problems such as a stepwise junction depth of SDE, and an increase in the number of manufacturing process steps.

US Patent Publication No. 6380039 discloses a technology for forming SDE with two steps in which an increase in the number of manufacturing process steps is suppressed. According to the technology, a sidewall of a gate electrode is formed by a well-known technology. In the formation of the sidewall, a base insulator outside the gate sidewall is exposed but should not be thinned. Subsequently, the exposed portion of the base insulator is thinned by using the sidewall as a mask, forming the base insulator with two steps. Dopants are implanted through the stepped base insulator thus forming a stepped SDE. Accordingly, SDE of the two steps is formed through a simplified process. However, there is a problem that the number of manufacturing steps is increased when the number of SDE steps is increased.

US Patent Publication No. 6054356 discloses a technology for forming a SDE with inclined junction depth. According to the technology, a spin-on glass (SOG) film is formed by spin coating after a gate electrode is formed, thereby forming SOG film having a thickness distribution in which it is thicker near the gate electrode and is gradually thinner as apart from the same. Ion implantation is carried out through the SOG film to form the inclined junction SDE in which a junction depth continuously changes. However, it is extremely difficult to form a thin SOG film to have a thickness of several 10 nm near the gate electrode and thinner thickness as apart from the gate electrode.

### BRIEF SUMMARY OF THE INVENTION

According to one aspect of the present invention, it is provided a semiconductor device comprising: a gate electrode formed on a semiconductor substrate of a first conductivity type via a gate insulator; a semiconductor region of a second conductivity type comprising first and second semiconductor areas, wherein the first semiconductor area is formed in the semiconductor substrate outside the gate electrode and whose junction depth becomes deeper as apart from the gate electrode, and wherein the second semiconductor area is disposed outside the first semiconductor area and whose junction depth is substantially constant; and an insulator formed to cover a part of the first semiconductor area and in contact with a side face of the gate electrode.

According to another aspect of the present invention, it is provided a semiconductor device comprising: a gate electrode formed on a semiconductor substrate of a first conductivity type via a gate insulator; a semiconductor region of a second conductivity type comprising first and second semiconductor areas, wherein the first semiconductor area is formed in the semiconductor substrate outside the gate electrode and whose junction depth becomes deeper as apart from the gate electrode, and wherein the second semiconductor area is disposed outside the first semiconductor area and whose junction depth is substantially constant; and an insulator formed on the first semiconductor area and being thinned as apart from the gate electrode.

According to still another aspect of the present invention, it is provided a method for manufacturing a semiconductor device, comprising: forming a gate electrode on a semiconductor substrate of a first conductivity type via a gate insulator; forming a first sidewall insulator in contacting with the gate electrode on the semiconductor substrate adjacent to the gate electrode; forming a first semiconductor area of a second conductivity type in the semiconductor substrate by using the gate electrode and the first sidewall insulator as masks; removing the first sidewall insulator; forming a second semiconductor area of the second conductivity type whose junction depth is shallower than that of the first semiconductor area in the semiconductor substrate by using the gate electrode as a mask; forming a second sidewall insulator in contacting with the gate electrode on the semiconductor substrate adjacent to the gate electrode, wherein the second sidewall insulator is thinner than the first sidewall insulator; and forming a third semiconductor area of the second conductivity type whose junction depth is deeper than that of the second semiconductor area and shallower than that of the first semiconductor area in the semiconductor substrate by using the gate electrode and the second sidewall insulator as masks.

According to still another aspect of the present invention, it is provided a method for manufacturing a semiconductor device, comprising: forming a gate electrode on a semiconductor substrate of a first conductivity type via a gate insulator; forming a insulator having a thickness distribution on the semiconductor substrate adjacent to the gate electrode; and forming a semiconductor area of a second conductivity type having a junction depth distribution dependent on the thickness distribution of the insulator and being doped with dopants through the insulator.

### BRIEF DESCRIPTION OF THE SEVERAL VIEWS OF THE DRAWING

FIG. 1 is a diagram showing a relation between the number of steps of source/drain extension (SDE) and a sheet resistance of SDE;

FIG. 2 is a sectional view shown to explain an example of a semiconductor device according to a first embodiment of the present invention;

FIGS. 3A, 3B, 3C, 3D, 3E, 3F, and 3G are process sectional views shown to explain an example of a manufacturing process of the semiconductor device according to the first embodiment of the present invention;

FIG. 4 is a sectional view shown to explain an example of a semiconductor device according to a second embodiment of the present invention;

FIGS. 5A, 5B, and 5C are process sectional views shown to explain an example of a manufacturing process of the semiconductor device according to the second embodiment of the present invention;

FIG. 6 is a sectional view shown to explain a semiconductor device according to a modified example of the second embodiment of the present invention; and

FIGS. 7A, 7B, 7C, 7D and 7E are process sectional views shown to explain an example of a manufacturing process of the semiconductor device according to the modified example of the second embodiment.

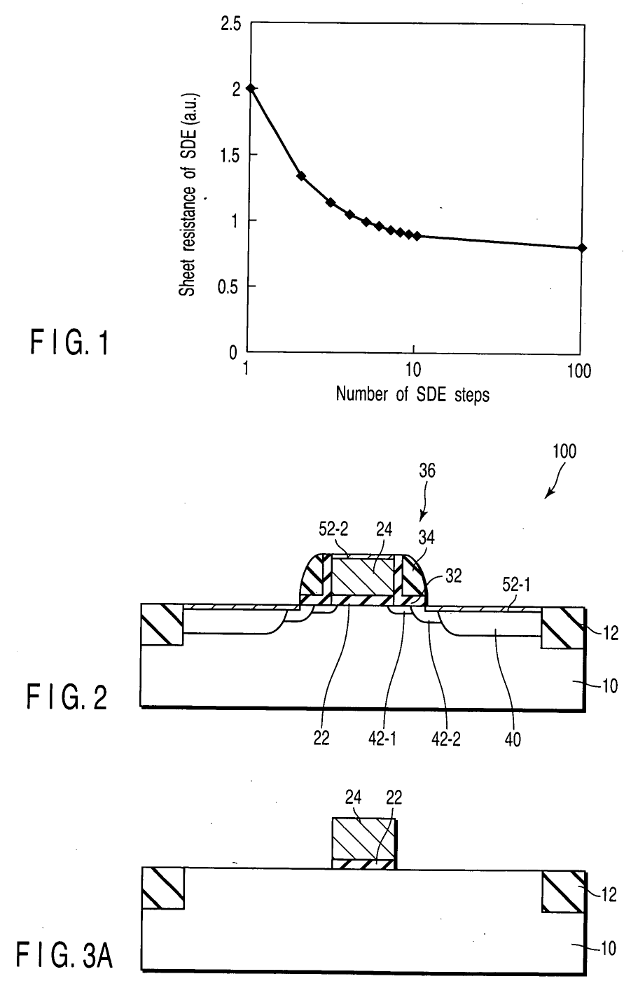

### DETAILED DESCRIPTION OF THE INVENTION

The embodiments of the present invention will be described with reference to the accompanying drawings. Throughout the drawings, corresponding portions are denoted by corresponding reference numerals. Each of the following embodiments is illustrated as one example, and therefore the present invention can be variously modified and implemented without departing from the spirits of the present invention.

### FIRST EMBODIMENT

A first embodiment of the present invention is directed to a semiconductor device having a structure in which a sidewall of a gate electrode is made thin to enable to form a silicide layer to extend from a source/drain (SD) surface to SDE even if SDE is formed into a stepped shape. As the silicide layer is formed closer to the gate electrode, it can be suppressed an increase in the parasitic resistance of SDE.

FIG. 2 shows an example of a sectional structure of the semiconductor device 100 of the embodiment. According to the embodiment, SDE is formed into two steps 42-1, 42-2, and a SD 40 is formed in the outside thereof. A gate sidewall 36 is generally formed into a structure to slightly overlap with SD in a horizontal direction. However, according to the embodiment, the gate sidewall 36 is formed narrow to slightly overlap with the outer SDE 42-2. And, a silicide layer 52-1 is formed on SDE 42-2 and SD 40 outside the gate sidewall 36, and a silicide layer 52-2 is formed on a gate electrode 24. Accordingly, the silicide layer 52-1 on SDE 42-2 is formed closer to the gate electrode than that in the general structure, that is formed on SD 42, thereby an increase in parasitic resistance can be suppressed even if SDE is formed in a stepped structure.

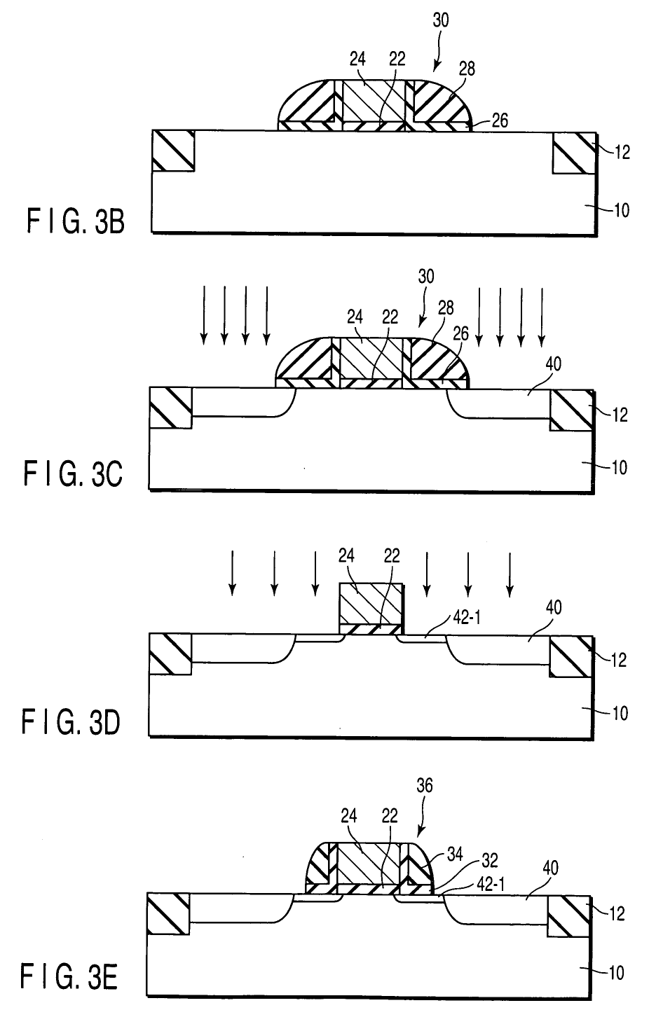

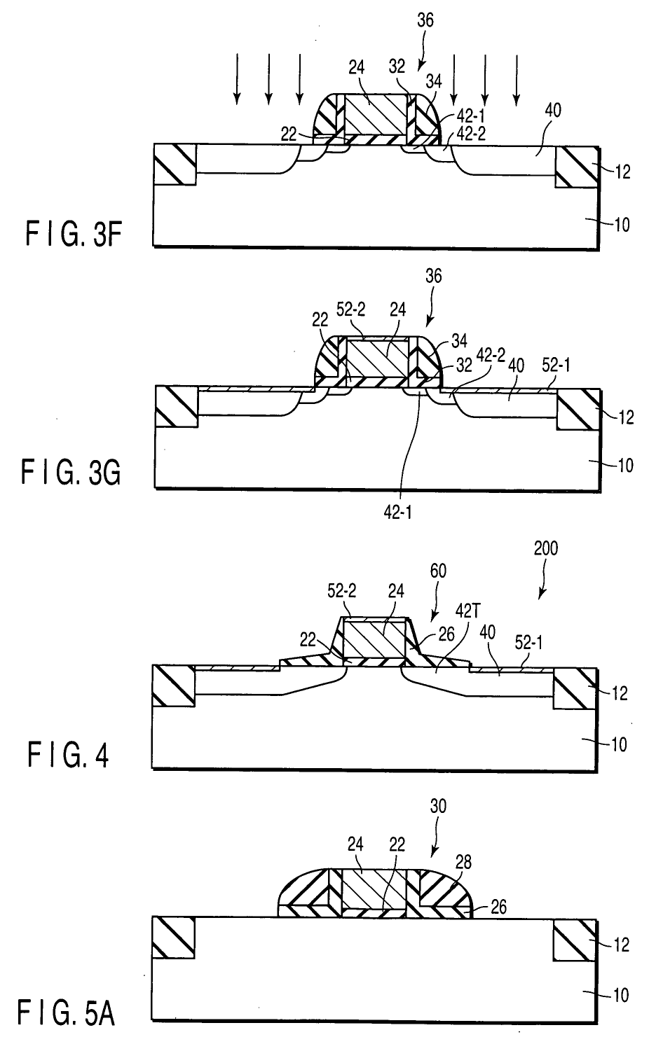

An example of a manufacturing process of the semiconductor device 100 of the present embodiment will be described by referring to FIGS. 3A to 3G.

(1) First, referring to FIG. 3A, a well (not shown) and an isolation 12 are formed in a semiconductor substrate 10, e.g., a silicon substrate. For the isolation 12, for example, a so-called shallow trench isolation (STI) in which a shallow trench is formed in the silicon substrate 10, and the trench is filled with, for example, silicon oxide (SiO₂) formed by chemical vapor deposition (CVD) can be used. Then, a gate insulator 22 is formed on an entire surface. For the gate insulator, for example, SiO₂ or silicon oxynitride (SiON) can be used. A conductive material for a gate electrode 24, e.g., polycrystal silicon doped with phosphorus (P) in a high concentration, is deposited on the gate insulator 22. The conductive material for the gate electrode is patterned into the gate electrode 24 by lithography and etching.

(2) Next, as shown in FIG. 3B, a first gate sidewall 30 is being formed. First and second insulators 26 and 28 are sequentially formed over an entire surface of the silicon substrate 10 including the gate electrode 24. For the first insulator 26, for example, silicon nitride (SiN) can be used. For the second insulator 28, for example, CVD-SiO₂ can be used. Then, the second and first insulators 28 and 26 are sequentially removed by anisotropic etching to form a first gate sidewall 30 as shown in FIG. 3B.

(3) Next, as shown in FIG. 3C, a source/drain (SD) 40 is being formed. Dopants with a conductivity type different from those of the silicon substrate 10 (well), e.g., arsenic (As) or boron (B), are implanted by using the first gate sidewall 30 and the gate electrode 24 as masks. Then, a heat treatment is carried out to electrically activate the implanted dopants, thereby SD 40 is formed.

(4) Next, as shown in FIG. 3D, first SDE 42-1 is being formed. The first gate sidewall 30 is removed to expose the silicon substrate 10. Then, dopants with the same conductivity type of SD 40 are implanted shallower than SD 40 using the gate electrode 24 as a mask. Subsequently, a heat treatment is carried out to electrically activate the implanted dopants, thereby first SDE 42-1 whose junction depth is shallower than that of SD 40 is formed.

It is to be noted that SD 40 and first SDE 42-1 can be formed in any orders.

(5) Next, as shown in FIG. 3E, a second gate sidewall 36 is being formed. Third and fourth insulators 32 and 34 are sequentially formed over an entire surface of the silicon substrate 10 including the gate electrode 24. The fourth insulator 34 is formed thinner than the second insulator 28. Preferably, the third insulator 32 is also formed thinner than the first insulator 26. For the third insulator 32, as in the case of the first insulator 26, for example, silicon nitride (SiN) can be used. For the fourth insulator 34, as in the case of the second insulting film 28, for example, CVD-SiO₂ can be used.

Then, the fourth and third insulators 34 and 32 are sequentially removed by anisotropic etching, thereby a second gate sidewall 36 narrower than the first gate sidewall 30 can be formed as shown in FIG. 3E. In other words, an edge of the second gate sidewall 36 is positioned between SD 40 and an edge of the gate electrode 24. By this anisotropic etching, the silicon substrate 10 outside the second gate sidewall 36 and a surface of the gate electrode 24 are exposed.

(6) Next, referring to FIG. 3F, second SDE 42-2 is being formed. Dopants with the same conductivity type of those of SD 40 are implanted shallower than SD 40 and deeper than first SDE 42-1 using the second gate sidewall 36 and the gate electrode 24 as masks. Subsequently, a heat treatment is carried out to electrically activate the implanted dopants, thereby second SDE 42-2 whose junction depth is shallower than that of SD 40 and deeper than that of the first SDE 42-1 is formed between SD 40 and the gate electrode 24.

It is to be noted that heat treatments to electrically activate the dopants implanted to form SD 40 and first and second SDE 42-1 and 42-2 are carried out either separately, or any of them together.

Thus, SDE 42-1, 42-1 having the stepped junction depth can be formed.

(7) Next, as shown in FIG. 3G, silicide layers 52-1, 52-2 are being formed on the second SDE 42-2 and SD 40, and on the gate electrode 24. A silicide metal (not shown) is deposited over an entire surface including the gate electrode 24. For the silicide metal, for example, nickel (Ni), cobalt (Co), titanium (Ti), or a high-meting point metal, such as molybdenum (Mo) or tungsten (W), can be used. The silicide metal comes into contact with the silicon substrate 10 exposed in the step (5) and the top surface of the gate electrode 24. Subsequently, a heat treatment is carried out to cause reaction between silicide metal and silicon, thereby silicide layers 52-1, 52-2 are formed on the surfaces of the second SDE 42-2 and SD 40 and the top surface of the gate electrode 24, respectively.

Then, an unreacted silicide metal is removed to complete a structure shown in FIG. 3G.

Accordingly, as the silicide layer 52-1 can be formed inner side of SD 40 and closer to the gate electrode 24, it can be suppressed an increase in parasitic resistance of SDE even when the SDE is formed in a stepped junction depth structure.

Subsequently, steps such as multilevel wiring necessary for the semiconductor device are carried out to complete the same. Thus, it can be manufactured a semiconductor device capable of suppressing an increase in the parasitic resistance of SDE and suitable for miniaturization.

In the semiconductor device 100 according to the present embodiment, although the junction depth of SDE is stepwise, it can be suppressed an increase in parasitic resistance of SDE since the silicide layer 52-1 can be formed inner side of SD 40 closer to the gate electrode 24.

### SECOND EMBODIMENT

A second embodiment of the present invention is directed to a semiconductor device which comprises SDE having an inclined junction depth.

As shown in FIG. 4, according to the present embodiment, the semiconductor device 200 comprises a sidewall 60 of a gate electrode 24 having an L-shape and changing its thickness. A SDE 42T comprising an inclined junction depth is formed by implanting dopant ions through the sidewall 60 having a thickness distribution.

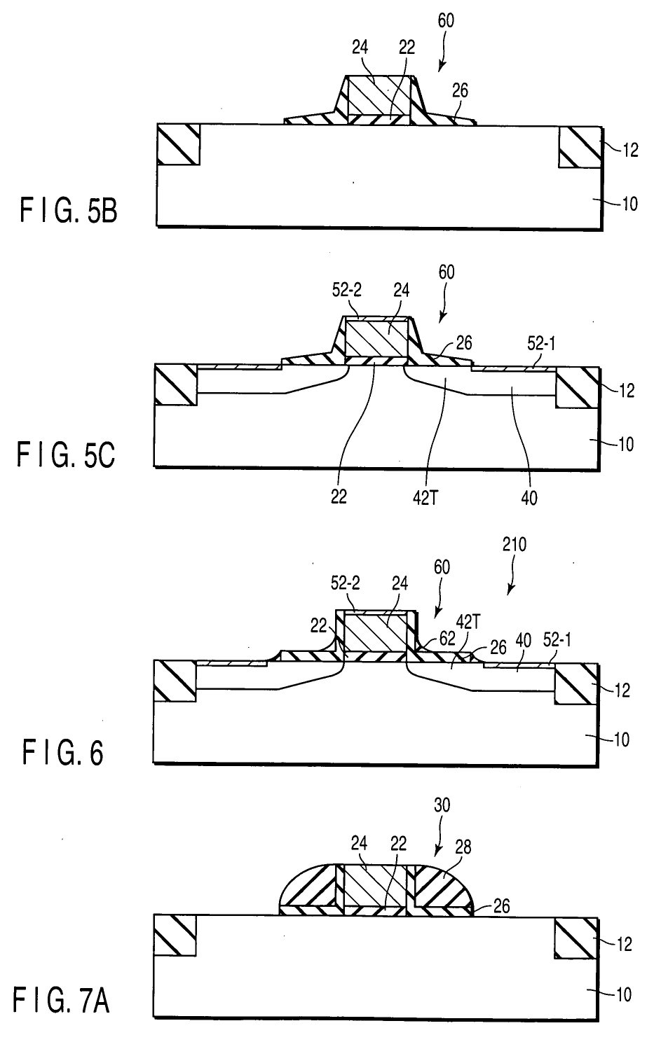

An example of a manufacturing process of the semiconductor device 200 of the embodiment will be described by referring to FIGS. 5A to 5C.

(1) FIG. 5A shows a gate electrode 24 and a first gate sidewall 30 comprising first and second insulators 26 and 28 are formed on a semiconductor substrate 10, e.g., a silicon substrate 10, as in the case of FIG. 3B. A manufacturing process thus far is similar to that of the steps (1) and (2) of the first embodiment, and thus description thereof will be omitted.

In the FIG. 5A, although it is depicted as the first insulator 26 is removed completely, all or a part of the first insulator 26 can be left on the silicon substrate 10 outside of the first gate sidewall 30.

(2) Next, referring to FIG. 5B, the second insulator 28 is removed by isotropic etching. In the isotropic etching, an etching speed of the second insulator 28 is set larger than that of to the first insulator 26, for example, an etching speed ratio is set to 5:1 to 10:1. By such isotropic etching, as the second insulator 28 is removed earlier at a portion apart from a corner of the sidewall 60, the first insulator 26 at a portion apart from an L-shaped corner is etched more to be thinner, and at the corner portion it becomes thicker.

Accordingly, it can be formed a thickness distribution to the first insulator 26 on the substrate 10, which is the sidewall 60.

It is to be noted that the second insulator 28 can be replaced with any material other than the insulator, e.g., amorphous silicon, as far as the material can be served as a mask layer and etched as described above.

(3) Next, dopants with a different conductivity type from those of the silicon substrate 10 (well), e.g., arsenic (As) or boron (B), are implanted through the sidewall 60 having a thickness distribution by using the gate electrode 24 as a mask. A projection depth of the implanted dopants in the silicon substrate 10 has an inclined distribution in which it is shallower below a thicker portion of the sidewall 60 and deeper below a thinner portion thereof. That is, dopants are implanted more deeply below a portion of no sidewall 60. Then, a heat treatment is carried out to electrically activate the implanted dopants, thereby SDE 42T having an inclined junction depth and SD 40 can be simultaneously formed as shown in FIG. 5C. An dopant concentration of SDE 42T becomes higher as apart from the gate electrode.

Subsequently, silicide layers 52-1, 52-2 are formed on SD 40 and the gate electrode 24 to complete a structure shown in FIG. 5C, as described above in step (7) of the first embodiment.

Further, steps such as multilevel wiring necessary for the semiconductor device are carried out to complete the semiconductor device 200 of the embodiment.

According to the semiconductor device 200 of the embodiment, as SDE has the inclined junction depth, it can be suppressed an increase in its parasitic resistance. Moreover, as SDE 42T and SD 40 can be formed by ion implantation executed only once through the sidewall 60 having the thickness distribution, it can be simplified the manufacturing process.

(Modification of Second Embodiment)

The second embodiment can be variously modified to be implemented. FIG. 6 shows one example of the modification thereof. The modification of the second embodiment of the present invention is directed to a semiconductor device 210 which comprises SDE 42T having an inclined junction depth formed by implanting dopant ions through a sidewall 60 having a thickness distribution. The sidewall 60 includes a first L-shaped insulator 26 disposed on a side face of a gate electrode 24 and silicon substrate 10, and a fifth insulator 62 formed in a reentrant portion of the first insulator 26 to make the thickness distribution.

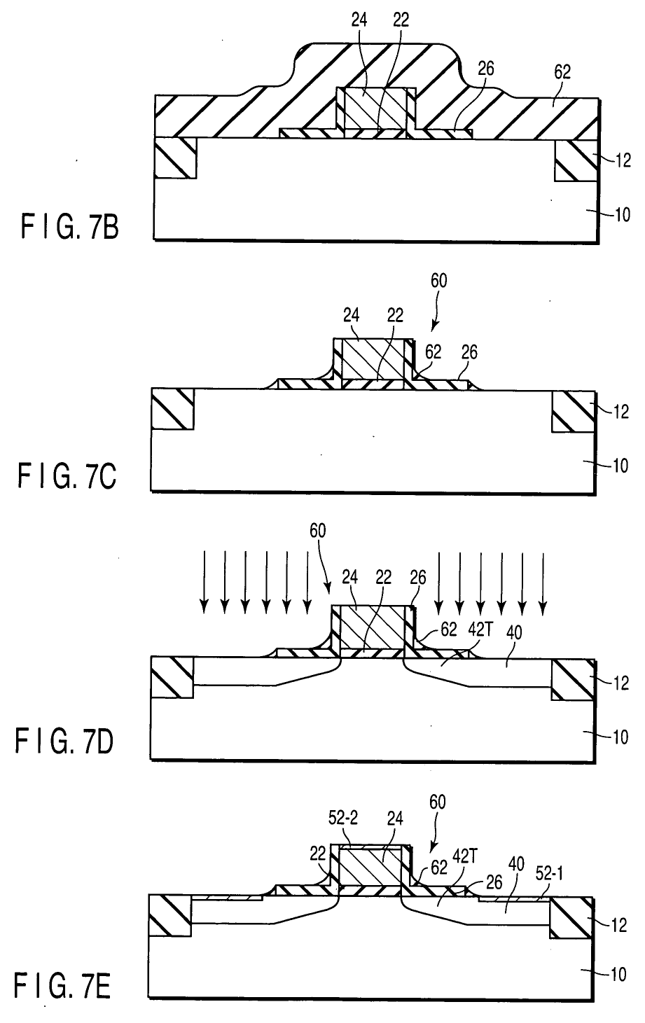

An example of a manufacturing process of the semiconductor device of the embodiment will be described by referring to FIGS. 7A to 7E.

(1) FIG. 7A shows a gate electrode 24 and a first gate sidewall 30 comprising first and second insulators 26 and 28 are formed on a semiconductor substrate 10, e.g., a silicon substrate 10, as in the case of FIG. 3B. A manufacturing process thus far is similar to that of the steps (1) and (2) of the first embodiment, and thus description thereof will be omitted.

(2) Next, referring to FIG. 7B, the second insulator 28 of the first gate sidewall 30 is removed while a L-shaped first insulator 26 is left on the side of the gate electrode 24.

It is to be noted that the second insulator 28 can be replaced with any material other than the insulator, e.g., amorphous silicon doped with dopants in a high concentration, as far as the material can be used as a mask layer for forming the L-shaped first insulator 26.

Then, a fifth insulator 62 is formed over an entire surface including the gate electrode 24 and the first insulator 26. For the fifth insulator 62, for example, CVD-SiO₂ can be used. This fifth insulator 62 is deposited more thickly in a reentrant portion of the first insulator 26 than a flat portion thereof, and more thinly in a salient angle portion than the same. As a result, the entire section is formed into a rounded shape.

Then, the fifth insulator 62 is removed by isotropic etching. In the isotropic etching, an etching condition is set to selectively etch the fifth insulator 62 and hardly etch the first insulator 26. According to the isotropic etching, the fifth insulator 62 in the reentrant portion of the first insulator 26 is thicker than the flat portion as described above. Thus, even if the fifth insulator 62 on the flat portion is removed to expose the first insulator 26, the fifth insulator 62 in the reentrant portion is left without being completely removed.

Accordingly, as shown in FIG. 7C, it can be formed a sidewall 60 comprised of the first and fifth insulator having a thickness distribution thicker closer to the gate electrode 24 and thinner as apart from the same.

(3) Next, referring to FIG. 7D, dopants with different conductivity type from those of the silicon substrate 10 (well), e.g., arsenic (As) or boron (B), are implanted through the sidewall 60 having the thickness distribution by using the gate electrode 24 as a mask. A projection depth of the implanted dopants in the silicon substrate 10 has an inclined distribution in which it is shallower below a thick portion of the sidewall 60 and deeper below a thin portion. Additionally, dopants are implanted more deeply in a portion of no sidewall 60. Then, a heat treatment is carried out to electrically activate the implanted dopants, thereby a SDE 42T having an inclined junction depth and a SD 40 can be simultaneously formed. A dopant concentration of SDE 42T is higher as apart from the gate electrode.

Subsequently, as described above in the step (7) of the first embodiment, silicide layers 52-1, 52-2 are formed on SD 40 and the gate electrode 24 (FIG. 7E). Further, steps such as multilevel wiring necessary for the semiconductor device are carried out to complete the semiconductor device 210 of the modification.

According to the semiconductor device 210 of the modification, as SDE 42T has the inclined junction depth, it can be suppressed an increase in its parasitic resistance. Moreover, as SDE 42T and SD 40 can be formed by ion implantation executed only once through the sidewall 60 having the thickness distribution, it can be simplified the manufacturing process.

Thus, it can be manufactured a semiconductor device capable of suppressing an increase in parasitic resistance of SDE and suitable for miniaturization.

As described above, according to the present invention, it can be provided a semiconductor device capable of reducing parasitic resistance of SDE even when the device is miniaturized, and its manufacturing method.

The above embodiments of the present invention are not limitative of the shape of SDE junction and the insulators formed through the ion implantation, but various modifications can be made and implemented.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A semiconductor device comprising:
a gate electrode formed on a semiconductor substrate of a first conductivity type via a gate insulator;
a semiconductor region of a second conductivity type comprising first and second semiconductor areas, wherein the first semiconductor area is formed in the semiconductor substrate outside the gate electrode and whose junction depth becomes deeper as apart from the gate electrode, and wherein the second semiconductor area is disposed outside the first semiconductor area and whose junction depth is substantially constant; and
an insulator formed to cover a part of the first semiconductor area and in contact with a side face of the gate electrode.

2. The semiconductor device according to claim 1, further comprising a silicide layer formed in the first and second semiconductor areas outside the insulator.

3. The semiconductor device according to claim 1, wherein the junction depth of the first semiconductor area changes stepwise below the insulator.

4. The semiconductor device according to claim 3, further comprising a silicide layer formed in the first and second semiconductor areas outside the insulator.

5. The semiconductor device according to claim 1, wherein the first semiconductor area has two or more steps of junction depth which changes stepwise.

6. The semiconductor device according to claim 1, wherein an impurity concentration of the first semiconductor area becomes higher as apart from the gate electrode.

7. A semiconductor device comprising:
a gate electrode formed on a semiconductor substrate of a first conductivity type via a gate insulator;
a semiconductor region of a second conductivity type comprising first and second semiconductor areas, wherein the first semiconductor area is formed in the semiconductor substrate outside the gate electrode and whose junction depth becomes deeper as apart from the gate electrode, and wherein the second semiconductor area is disposed outside the first semiconductor area and whose junction depth is substantially constant; and
an insulator formed on the first semiconductor area and being thinned as apart from the gate electrode.

8. The semiconductor device according to claim 7, wherein the insulator comprises one insulator having a thickness distribution.

9. The semiconductor device according to claim 7, wherein the insulator comprises a first insulator portion having a substantially constant thickness and a second insulator portion added to provide a thickness distribution.

10. The semiconductor device according to claim 7, further comprising a silicide layer formed in the second semiconductor area outside the insulator.

11. The semiconductor device according to claim 7, wherein an impurity concentration of the first semiconductor area becomes higher as apart from the gate electrode.

12. A method for manufacturing a semiconductor device, comprising:
forming a gate electrode on a semiconductor substrate of a first conductivity type via a gate insulator;
forming a first sidewall insulator in contacting with the gate electrode on the semiconductor substrate adjacent to the gate electrode;
forming a first semiconductor area of a second conductivity type in the semiconductor substrate by using the gate electrode and the first sidewall insulator as masks;
removing the first sidewall insulator;
forming a second semiconductor area of the second conductivity type in the semiconductor substrate by using the gate electrode as a mask, wherein a junction depth of the second semiconductor area is shallower than that of the first semiconductor area;
forming a second sidewall insulator in contacting with the gate electrode on the semiconductor substrate, wherein the second sidewall insulator is thinner than the first sidewall insulator; and
forming a third semiconductor area of the second conductivity type in the semiconductor substrate by using the gate electrode and the second sidewall insulator as masks, wherein a junction depth of the third semiconductor area is deeper than that of the second semiconductor area and shallower than that of the first semiconductor area.

13. The method according to claim 12, further comprising:
forming a silicide layer in the first and third semiconductor areas outside the insulator.

14. The method of claim 12, wherein an impurity concentration in the second, third, and first semiconductor area becomes higher as apart from the gate electrode.

15. A method for manufacturing a semiconductor device, comprising:
forming a gate electrode on a semiconductor substrate of a first conductivity type via a gate insulator;
forming a insulator having a thickness distribution on the semiconductor substrate adjacent to the gate electrode; and
forming a semiconductor area of a second conductivity type having a junction depth distribution dependent on the thickness distribution of the insulator and being doped with dopants through the insulator.

16. The method according to claim 15, further comprising:
forming a silicide layer in the semiconductor area outside the insulator.

17. The method according to claim 15, wherein an impurity concentration of the semiconductor area becomes higher as apart from the gate electrode.

18. The method according to claim 15, wherein the step of forming the insulator having the thickness distribution, comprises:
sequentially depositing a first insulator and a mask layer over an entire surface of the semiconductor substrate including the gate electrode;
forming a sidewall by an isotropically etching the mask layer and the first insulator; and
removing the mask layer from the sidewall by isotropic etching, in which an etching speed for the first insulator is lower than an etching speed for the mask layer, to form the insulator comprised of the first insulator and having the thickness distribution.

19. The method according to claim 18, further comprising:
forming a silicide layer in the semiconductor area outside the insulator.

20. The method according to claim 15, wherein the forming the insulator having the thickness distribution, comprises:
sequentially depositing a first insulator and a mask layer over an entire surface of the semiconductor substrate including the gate electrode;
forming a sidewall by an isotropically etching the mask layer and the first insulator;
removing the mask layer from the sidewall;
depositing a second insulator over an entire surface of the semiconductor substrate including the gate electrode and the first insulator; and
isotropically etching the third insulator to form the insulator comprised of first and third insulators and having a thickness distribution.
